(19) United States
(12) Patent Application Publication
(10) Pub. No.: US 2018/0349752 A1
(43) Pub. Date: Dec. 6, 2018

(54) FABRICATION OF AN SD CARD INSERTED ELECTRONIC OR A PLAIN IDENTIFICATION CARD

(71) Applicant: SRIKANTH TATINENI, Hyderabad (IN)

(72) Inventor: SRIKANTH TATINENI, Hyderabad (IN)

(21) Appl. No.: 15/778,234

(22) PCT Filed: Jan. 3, 2016
(86) PCT No.: PCT/IB2016/050010

§ 371 Date: May 23, 2018

(30) Foreign Application Priority Data
Nov. 23, 2015 (IN) 6283/CHE/2015

(51) Int. Cl. G06K 19/077; G11C 11/21

(52) U.S. Cl. CPC G06K 19/07747; G06K 19/07722; G06K 19/07732; G11C 11/21

(57) ABSTRACT

An electronic or a plain identification card to hold an SD card in a unique way provided with a stored memory and a header for interfacing with an electronic port of a reader device is disclosed. The electronic identification card comprises a card body provided with a recess to hold the SD card with the help of an adhesive means, a plurality of contact connections to supply power when connected to a host, a plurality of protection layers at the top and bottom surface of the electronic identification card preventing any slippage of SD card. The recess can be provided at any location on the electronic or a plain identification card to incorporate an SD card used for identifying an intended holder of a device through the memory stored in the card.

### TECHNICAL FIELD

The present invention relates to a fabrication of an SD card inserted electronic or a plain identification card. More particularly, the present invention relates to a method of fabricating an electronic or a plain identification card integrated with a secure digital (SD) card to prevent any loss of it and replaces traditional identification cards.

### BACKGROUND

A popular type of storage device of non-volatile SD card is a secure digital (SD) card or a memory card are used for storing information, programs, files, documents etc. As these cards are available in very small & variable sizes and capacities, care should be taken while storing the SD card to avoid any loss of it. Variety of holders available to accommodate SD cards in the slots provided on it and to be locked in order to avoid loss. However, still there is a chance of loss of these cards as there is no provision of enclosing the housing from all sides. Therefore there is a need to develop a means to store the SD card or a memory card handy that are used for storing the digital information, re-recordable and can retain data without power.

Therefore there is a need to provide a means to hold SD cards in a unique way which is embedded in electronic identification means to avoid any loss of the SD cards.

### BRIEF SUMMARY

The present invention recognizes the limitations of the prior art and the need for systems and methods that are able to provide assistance to users in a manner that overcomes these limitations.

Another principal object of the present invention is to incorporate an SD card into an electronic or a plain identification card at any place of a card body.

Another object of the present invention is to provide at least one recess on the card body of the electronic or a plain identification card.

Another object of the present invention is to provide a plurality of contact connections in the proximity of the recess holding the SD card to supply power used for communication between the smart identification card when inserted into a reader and connected to a host.

Yet another object of the present invention is to provide a plurality of protection layers at the top and bottom of the smart identification card to avoid any slippage of an SD card out of it include but not limited to a wax layer or a lamination layer or nearby embossing or the like.

According to a first aspect of the present invention, a process of incorporating at least one secure digital (SD) card in an electronic or a plain identification card body is disclosed. The process comprises of steps of electronic making at least one recess on the electronic identification card body, incorporating a plurality of contact connections in a proximity of the recess of the said electronic identification card body and applying an adhesive at the points of contact connections of the electronic identification card.

In accordance with a first aspect of the present invention, further the process comprises steps of incorporating the said SD card in the recess provided on the said card body by applying pressure at the adhesive contact connections and providing a plurality of protection layers at the top and bottom of the electronic identification card to avoid any slippage of the said SD card that is incorporated.

In accordance with a first aspect of the present invention, a further step of the process is to provide a the recess on the card body is provided according to the size, shape, length and thickness of the SD card that is to be inserted in to the electronic identification card.

In accordance with a first aspect of the present invention, the process further comprises of accommodating a plurality of contact connections supply power to the card for communication between the electronic identification card when inserted into a reader and connected to a host.

In accordance with a first aspect of the present invention, further step of the process is to provide a plurality of protection layers avoiding slippage of the SD card include but not limited to a wax layer, a lamination layer and a nearby embossing layer or the like.

According to a second aspect of the present invention, an electronic identification card comprises of an identification card body, at least one electronic header, at least one inserted electronic memory, at least one electronic port of a reader device, encoded data programmed into the memory of the electronic header, the card including information relating to a and identifying an intended holder of a device and an attachment means for securing the identification card to the header piece via an edge of the identification card.

According to a third aspect of the present invention, an electronic or a plain identification card incorporating at least one secure digital (SD) card in the card body is disclosed. The electronic identification card comprises of a card body forming an electronic identification card, at least one secure digital (SD) card, at least one recess arranged on the said card body and a plurality of contact connections in the proximity of the recess of the said card body.

In accordance with a third aspect of the present invention, the card further comprises of an adhesive means applied at the points of the contact connections of the electronic identification card, a means for installing the said SD card in the recess provided on the said card body by applying pressure at the adhesive contact connections and a plurality of protection layers at the top and bottom of the electronic identification card to avoid any slippage of the said SD card.

In accordance with a third aspect of the present invention, wherein the electronic identification card body made from one or more materials include but not limited to a polycarbonate, a durable material, a paper material and a plastic material or the similar material.

In accordance with a third aspect of the present invention, wherein the card further comprises of a plurality of contact connections to supply power for enabling a communication between the electronic identification card and a reader when connected to a host.

In accordance with a third aspect of the present invention, further the card comprises plurality of protection layers to avoid slippage of the SD card include but not limited to a wax layer, a lamination layer and a nearby embossing layer or the like.

### BRIEF DESCRIPTION

Other objects and advantages of the present invention will become apparent to those skilled in the art upon reading the following detailed description of the preferred embodiments, in conjunction with the accompanying drawings, wherein like reference numerals have been used to designate like elements, and wherein

FIGS, la-If illustrates a card body of an electronic identification card provided with a plurality of recess arranged at appropriate location of the card body according to the present invention.

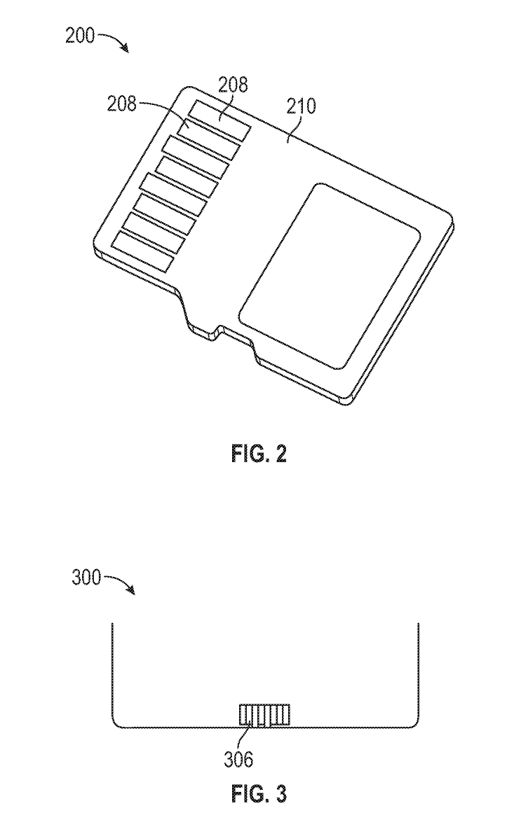

FIG. 2 illustrates an external view of an SD card incorporated into an electronic identification card according to a present invention.

FIG. 3 illustrates an external view of a contact connections provided at proximity of the recess according to the present invention.

### DETAILED DESCRIPTION

The use of “including”, “comprising” or “having” and variations thereof herein is meant to encompass the items listed thereafter and equivalents thereof as well as additional items. The terms “a” and “an” herein do not denote a limitation of quantity, but rather denote the presence of at least one of the referenced item. Further, the use of terms “first”, “second”, and “third”, and the like, herein do not denote any order, quantity, or importance, but rather are used to distinguish one element from another.

In accordance with an exemplary embodiment of the present invention, a process of incorporating at least one secure digital (SD) card in an electronic or a plain identification card body is disclosed. The process comprises of steps of electronic making at least one recess on the electronic identification card body, incorporating a plurality of contact connections in a proximity of the recess of the said electronic identification card body and applying an adhesive at the points of contact connections of the electronic identification card.

In accordance with an exemplary embodiment of the present invention, the process further comprises steps of incorporating the said SD card in the recess provided on the said card body by applying pressure at the adhesive contact connections and providing a plurality of protection layers at the top and bottom of the electronic identification card to avoid any slippage of the said SD card that is incorporated.

In accordance with an exemplary embodiment of the present invention, a further step of the process is to provide a recess on the card body according to the size, shape, length and thickness of the SD card that is to be inserted in to the electronic identification card.

In accordance with an exemplary embodiment of the present invention, the process further comprises a step of accommodating a plurality of contact connections supply power to the card for communication between the electronic identification card when inserted into a reader and connected to a host.

In accordance with an exemplary embodiment of the present invention, further step of the process is to provide a plurality of protection layers avoiding slippage of the SD card include but not limited to a wax layer, a lamination layer and a nearby embossing layer or the like.

In accordance with an exemplary embodiment of the present invention, an electronic or a plain identification card comprises of an identification card body, at least one electronic header, at least one inserted electronic memory, at least one electronic port of a reader device, encoded data programmed into the memory of the electronic header, the card including information relating to a and identifying an intended holder of a device and an attachment means for securing the identification card to the header piece via an edge of the identification card.

In accordance with an exemplary embodiment of the present invention, the electronic identification card comprises at least one secure digital (SD) card, at least one recess arranged on the said card body and a plurality of contact connections in the proximity of the recess of the said card body.

In accordance with an exemplary embodiment of the present invention, the card further comprises of an adhesive means applied at the points of the contact connections of the electronic identification card, a means for installing the said SD card in the recess provided on the said card body by applying pressure at the adhesive contact connections and a plurality of protection layers at the top and bottom of the electronic identification card to avoid any slippage of the said SD card.

In accordance with an exemplary embodiment of the present invention, wherein the electronic identification card body made from one or more materials include but not limited to a polycarbonate, a durable material, a paper material and a plastic material or the similar material.

In accordance with an exemplary embodiment of the present invention, wherein the card further comprises of a plurality of contact connections to supply power for enabling a communication between the electronic identification card and a reader when connected to a host.

In accordance with an exemplary embodiment of the present invention, further the card comprises plurality of protection layers to avoid slippage of the SD card include but not limited to a wax layer, a lamination layer and a nearby embossing layer or the like.

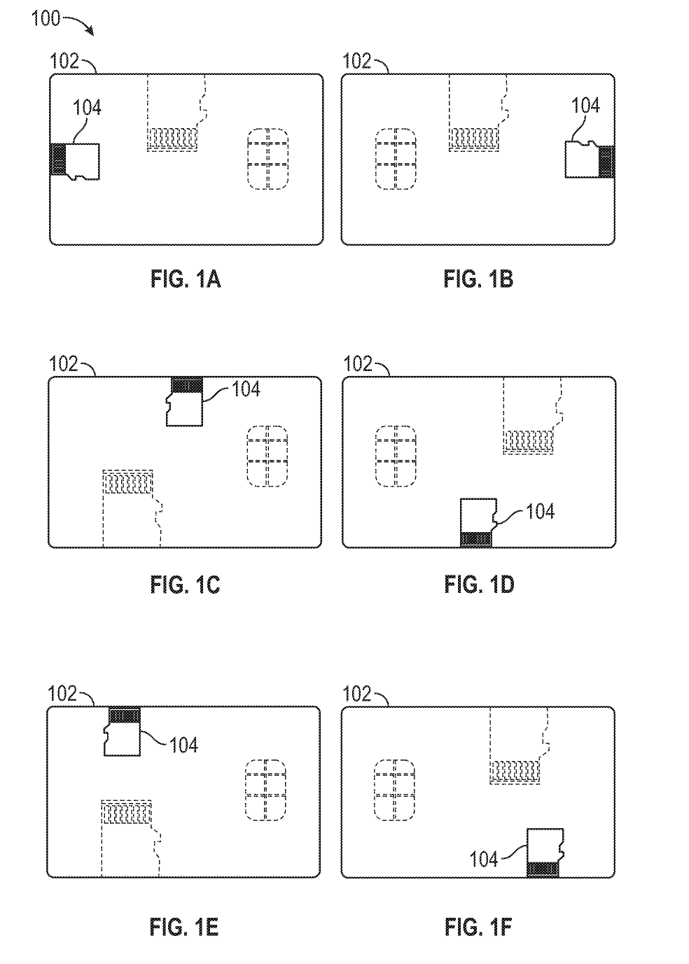

Referring to drawings, FIGS. 1-4 illustrate an exemplary embodiment of the present invention depicting the incorporation of an SD card. However, the present invention is not limited to the embodiment, and various modifications and changes in design can be made without departing from the scope of the present invention.

FIGS, la-If illustrates an electronic identification card 100 comprising a card body 102 made from one or more of the materials include polycarbonate or a durable material or a paper material or a plastic material or the similar material that is arranged at various locations in the card body as shown. This card body 102 forms the base of the electronic identification cards provided with an electronic header. The card 100 comprises an electronic memory storing the information relating to the electronic identification card holder more particularly, access information or an authentication data or a unique identification code or a biometric feature of electronic identification card holder. This information stored in the electronic memory in the form of encoded data programmed into memory of the electronic header.

The card body 102 is provided with a recess 104 for accommodating an SD card as shown in the FIG. 3. The electronic identification card of a holder accommodates one or more or all of the SD cards in the recess 104 provided on the card body 102. The card 100 also comprises an attachment means for securing it into the header piece through an edge of the card.

FIG. 2 illustrates of an electronic identification card 200 with a card body 202 with a plurality of contact connections 306 provided within the proximity of the recess to attach with the SD card's contact terminals 208 as shown in the FIG. 3. These contact connections 306 supply power for enabling a communication between the electronic identification card and a reader when connected to a host or a reader. At the point of contact connection there is placed an adhesive to install the SD card in the recess 104 provided on the identification card 300 by applying pressure at adhesive contact connections. The SD card 210 such inserted into the electronic identification card 300 is illustrated in the FIG. 2 comprising a plurality of contact terminals 208 which comes in contact with the contact connections 306 placed in the card body when connected to a host or a reader for identification of a holder. FIG. 3 illustrates an external view 300 of a contact connection 306 of an electronic identification card according to the present invention for the identification of a user which can be a an access information or an authentication data or a unique identification code or a biometric feature of electronic identification card holder.

Depending on the shape, size, length and thickness of the SD card to be incorporated into an electronic identification card the recess on the card body is provided. After incorporating the appropriate SD card into the electronic identification card a plurality of protection layers are applied on top and bottom surfaces of the card to avoid slippage of the SD card. These protection layers include one or more from a wax layer or a lamination layer or a nearby embossing layer or the like.

As such, the SD card inserted in to an electronic identification card can be of any size, shape, length, thickness and any number of cards can be incorporated according to the requirement as defined in the claims of the present invention. And accordingly, the size of the recess provided on the card body varies based on the SD card selected.

The above described preferred embodiments are intended to illustrate the principles of the invention but without limiting its scope. Other embodiments and variations to these preferred embodiments will be apparent to those skilled in the art and may be made without departing from the essence and scope of the invention as defined in the claims.

I/We claim:

1. A method for providing at least one secure digital (SD) card in an electronic identification card body or a plain identification card at pre-determined position, comprises the steps of:
i) Electronically etching out at least one recess of pre-conceived size, shape, length and thickness on the said electronic identification card body at predetermined location;
ii) Incorporating a plurality of electrical power and data communication contact connections placed adjacent and parallel to one another at the extreme end of the said recess enabling the communication between the said electronic ID card and the host. system;
iii) Establishing the data communication and the power management between the SD card incorporated in the said electronically etched out recess through the said contact connections and the external host system; and
iv) Enabling a permanent communication pathway for the transfer of stored encrypted data between the incorporated SD card and the electronic port of the reader device through the said electrical contact connections etched in the electronic identification card body.

2. The method for providing at least one secure digital (SD) card in an electronic identification card body or a plain identification card at pre-determined position as claimed in claim 1 wherein the said plurality of electrical power and data communication contact connections permanently etched on the surface of the said SD card establishes a physical contact with the said electrical power and data communication contacts of the SD memory and the host system.

3. The method for providing at least one secure digital (SD) card in an electronic identification card body or a plain identification card at pre-determined position as claimed in claim 1 wherein the said accommodated plurality of contact connections supply power to the card for communication between the electronic identification card when inserted into a reader and connected to a host.

4. The method for providing at least one secure digital (SD) card in an electronic identification card body or a plain identification card at pre-determined position as claimed in claim 1 wherein the said SD card is securely attached to the header piece through an attachment means for enablement of the encrypted data communication.

5. An electronic identification card, comprising
i) an identification card body characterized in that said E-ID card further comprises a plurality of adjacent and parallel located electronic contact connections permanently affixed at the extreme end of the said recess;
ii) At least one electronic header for establishing a data communication and power management for the said E ID card;
iii) At least one electronic SD memory removably attached to the said etched contact connections at the end of the said recess;
iv) At least one electronic port of a reader device compatible with the said contact connection;
v) Encrypted data and information relating to the said E ID card holder stored into the said memory of the electronic header; and
vi) An attachment means for securing the said identification card to the header piece via an edge of the identification card.

6. An electronic identification (E ID) card or a plain identification card comprises of:
i) A card body (102) forming an electronic identification card characterized in that said E ID card further comprises
ii) At least one recess of pre conceived shape, size, length and thickness electronically etched out at p re-determined position on the said card body;
iii) A plurality of parallel and adjacent located electronic contact connections (306) permanently affixed in the proximity of the said recess in the said card body (102);
iv) At least one secure digital (SD) card (104, 200) comprising means (208) for establishing a data communication and power management with the said contact connections (306) of the E ID card and the host system.
v) A permanent holding means engaging the said contact connections to the body of the said electronic identification card;
vi) A means for removably fixing the said SD card in the said recess etched on the said card body by the application of pressure at the said contact connections enabling the storage and transfer of encrypted data among the said E ID card, SD card and the external host system;

7. The electronic identification (E ID) card or a plain identification card as claimed in claim 6 wherein the said plurality of parallel and adjacent located electronic contact connections (306) at pre-determined location of the E ID card establishes the data communication and power management between the said removably fixed storage devices and the host system.

8. The electronic identification (E ID) card or a plain identification card as claimed in claim 6 wherein the said plurality of contact connections supply power for enabling a communication between the electronic identification card and a reader when connected to a host.

9. The electronic identification (E ID) card or a plain identification card as claimed in claim 6 wherein the said card is made from one or more materials include but not limited to polycarbonate; a durable material; a paper material; and a plastic material or the similar material and the said plurality of protection layers to avoid slippage of the SD card include but not limited to a wax layer; a lamination layer; a nearby embossing layer; and a dye mounding or the like.
